(19) United States
(12) Patent Application Publication
(10) Pub. No.: US 2011/0126877 A1
(43) Pub. Date: Jun. 2, 2011

(54) SOLAR CELL

(76) Inventors: Jinah KIM, Seoul (KR); Seunghwan SHIM, Seoul (KR); Juhong YANG, Seoul (KR); Ilhyoung JUNG, Seoul (KR)

(21) Appl. No.: 12/849,442

(22) Filed: Aug. 3, 2010

(30) Foreign Application Priority Data
Nov. 27, 2009 (KR) 10-2009-0115957
Dec. 7, 2009 (KR) 10-2009-0120414
Dec. 7, 2009 (KR) 10-2009-0120532
Feb. 1, 2010 (KR) 10-2010-0009029

(51) Int. Cl. H01L 31/042; H01L 31/0256; H01L 31/0288; H01L 31/0368; H01L 31/00

(52) U.S. Cl. 136/244; 136/261; 136/255; 136/258; 136/252

(57) ABSTRACT

A cell includes a substrate of a first conductive type, at least one emitter region of a second conductive type opposite to the first conductive type, and disposed at the substrate, a plurality of first electrodes electrically connected to the at least one emitter region, and at least one second electrode electrically connected to the substrate, wherein the substrate is a silicon substrate of a metallurgical grade.

### CROSS-REFERENCE TO RELATED APPLICATION

This application claims priority to and the benefit of Korean Patent Application No. 10-2009-0115957, 10-2009-0120532, 10-2009-0120414, and 10-2010-0009029, filed in the Korean Intellectual Property Office on Nov. 27, 2009, Dec. 7, 2009, Dec. 7, 2009, and Feb. 1, 2010, respectively, the entire contents of which are incorporated herein by reference.

### BACKGROUND OF THE INVENTION

(a) Field of the Invention

Embodiments of the present invention relate to a solar cell.

(b) Description of the Related Art

Recently, as existing energy sources such as petroleum and coal are expected to be depleted, interests in alternative energy sources for replacing the existing energy sources are increasing. Among the alternative energy sources, solar cells generating electric energy from solar energy have been particularly spotlighted. A silicon solar cell generally includes a substrate and an emitter region, each of which is formed of a semiconductor, and a plurality of electrodes respectively formed on the substrate and the emitter region. The semiconductors forming the substrate and the emitter region have different conductive types, such as a p-type and an n-type. A p-n junction is formed at an interface between the substrate and the emitter region.

When light is incident on the solar cell, a plurality of electron-hole pairs are generated in the semiconductors. The electron-hole pairs are separated into electrons and holes by the photovoltaic effect. Thus, the separated electrons move to the n-type semiconductor (e.g., the emitter region) and the separated holes move to the p-type semiconductor (e.g., the substrate), The electrons and holes are respectively collected by the electrode electrically connected to the emitter region and the electrode electrically connected to the substrate. The electrodes are connected to one another using electric wires to thereby obtain electric power.

### SUMMARY OF THE INVENTION

According to an aspect of the present invention, a solar cell may include a substrate of a first conductive type; at least one emitter region of a second conductive type opposite to the first conductive type, and disposed at the substrate; a plurality of first electrodes electrically connected to the at least one emitter region; and at least one second electrode electrically connected to the substrate, wherein the substrate is a silicon substrate of a metallurgical grade.

According to another aspect of the present invention, a solar cell may include a substrate of a first conductive type; at least one emitter region of a second conductive type opposite to the first conductive type; a plurality of first electrodes electrically connected to the at least one emitter region; and at least one second electrode electrically connected to the substrate, wherein the substrate has bulk lifetime of about 0.1 μs˜2 μs.

According to another aspect of the present invention, a solar cell may include a substrate of a first conductive type; at least one emitter region of a second conductive type opposite to the first conductive type, and disposed at the substrate; a plurality of first electrodes electrically connected to the at least one emitter region; and at least one second electrode electrically connected to the substrate, wherein the substrate has a purity level of 5N or less.

According to another aspect of the present invention, a solar cell may include a substrate of a first conductive type; at least one emitter region of a second conductive type opposite to the first conductive type, and disposed at the substrate; a plurality of first electrodes electrically connected to the at least one emitter region; and at least one second electrode electrically connected to the substrate, wherein the substrate is manufactured by using a method of melting a silicon raw material and a reactive material together in a furnace and removing impurities from the silicon raw material.

According to another aspect of the present invention, a solar cell may include a substrate of a first conductive type; at least one emitter region of a second conductive type opposite to the first conductive type; a plurality of first electrodes electrically connected to the at least one emitter region; and at least one second electrode electrically connected to the substrate, wherein the substrate is a polycrystalline silicon substrate with a purity level of 5N or less, and has bulk lifetime of 0.1 μs˜2 μs, boron density of 3×10¹⁶˜5×10¹⁸ atoms/cm^{3,} oxygen density of 1×10¹⁸˜1×10¹⁹ atoms/cm³ and carbon density of 1×10¹⁶˜1×10¹⁹ atoms/cm³.

According to another aspect of the present invention, a solar cell may include a substrate of a first conductive type; at least one emitter region of a second conductive type opposite to the first conductive type; a plurality of first electrodes electrically connected to the at least one emitter region; and at least one second electrode electrically connected to the substrate, wherein the substrate comprises aluminum material, and has bulk lifetime of 0.1 μs˜2 μs, boron density of 3×10¹⁶˜5×10¹⁸ atoms/cm^{3,} oxygen density of 1×10¹⁸˜1×10¹⁹ atoms/cm³ and carbon density of 1×10¹⁶˜1×10¹⁹ atoms/cm³.

According to another aspect of the present invention, a solar cell module may include a plurality of solar cells electrically connected in series; upper and lower protective layers that are respectively positioned on and under the plurality of solar cells; a transparent member positioned on the upper protective layer; and a back sheet positioned under the lower protective layer, wherein each of the plurality of solar cells includes a silicon substrate of a metallurgical grade.

According to another aspect of the present invention a solar cell may include a substrate of a first conductive type; at least one emitter region of a second conductive type opposite to the first conductive type, and disposed at the substrate; a plurality of first electrodes electrically connected to the at least one emitter region; and at least one second electrode electrically connected to the substrate, wherein the at least one emitter region includes a dopant of the second conductive type, the at least one emitter region has a concentration profile relative to depth of the dopant, and the concentration profile relative to depth includes a non-decreasing portion.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 illustrates a partial perspective view of a solar cell according to an embodiment of the present invention;

FIG. 2 illustrates a cross-sectional view of a solar cell cut along the II-II line shown in FIG. 1;

FIG. 3 illustrates a shape example of a textured surface of a substrate according to an embodiment of the present invention;

FIG. 4 illustrates density variation of activated impurities according to thickness variation of an emitter region according to an embodiment of the present invention and density variation of activated impurities according to thickness variation of an emitter region according to a comparative example;

FIG. 5 is a graph illustrating efficiency variation of a solar cell with respect to bulk lifetime of a substrate;

FIG. 6 is a graph illustrating variation of an efficiency of a solar cell as density of boron contained in a substrate is varied;

FIG. 7 is a graph illustrating variation of an efficiency of a solar cell as resistivity of a substrate is varied;

FIG. 8 illustrates a partial cross-sectional view of a solar cell according to another embodiment of the present invention;

FIGS. 9, 11, and 15 to 17 illustrate partial cross-sectional views of various solar cells according to other embodiments of the present invention;

FIGS. 10A to 10D are cross-sectional views sequentially illustrating a method for manufacturing the solar cell shown in FIG. 9;

FIGS. 12A to 12E are cross-sectional views sequentially illustrating a method for manufacturing the solar cell shown in FIG. 11;

FIGS. 13 and 14 are graphs illustrating reflectivity of light due to a first film and a second film respectively according to an embodiment of the present invention with respect to a wavelength of light; and

FIG. 18 illustrates a schematic cross-sectional view of a solar cell module according to embodiments of the present invention.

### DETAILED DESCRIPTION OF THE EMBODIMENTS

The invention will be described more fully hereinafter with reference to the accompanying drawings, in which example embodiments of the inventions are shown. This invention may, however, be embodied in many different forms and should not be construed as limited to only the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it may be directly on the other element or intervening elements may also be present. In contrast, when an element is referred to as being “directly on” another element, there are no intervening elements present. Further, it will be understood that when an element such as a layer, film, region, or substrate is referred to as being “entirely” on another element, it may be on the entire surface of the other element and may not be on a portion of an edge of the other element.

Hereinafter, according to the present invention, preferred embodiments of a solar cell will be described with reference to appended drawings.

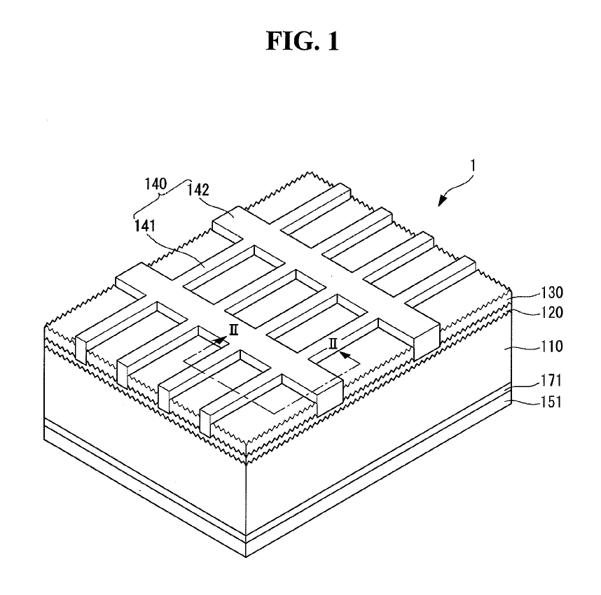

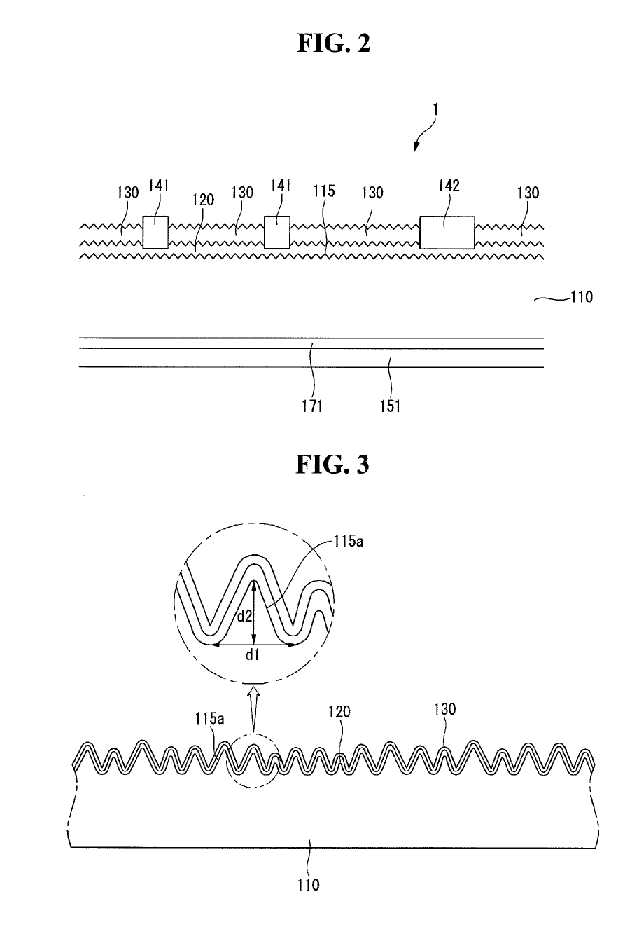

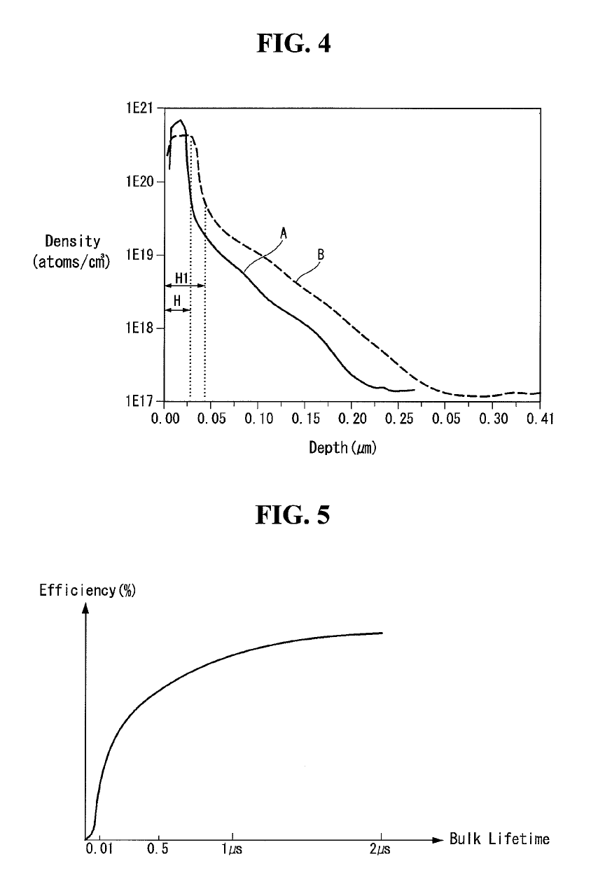

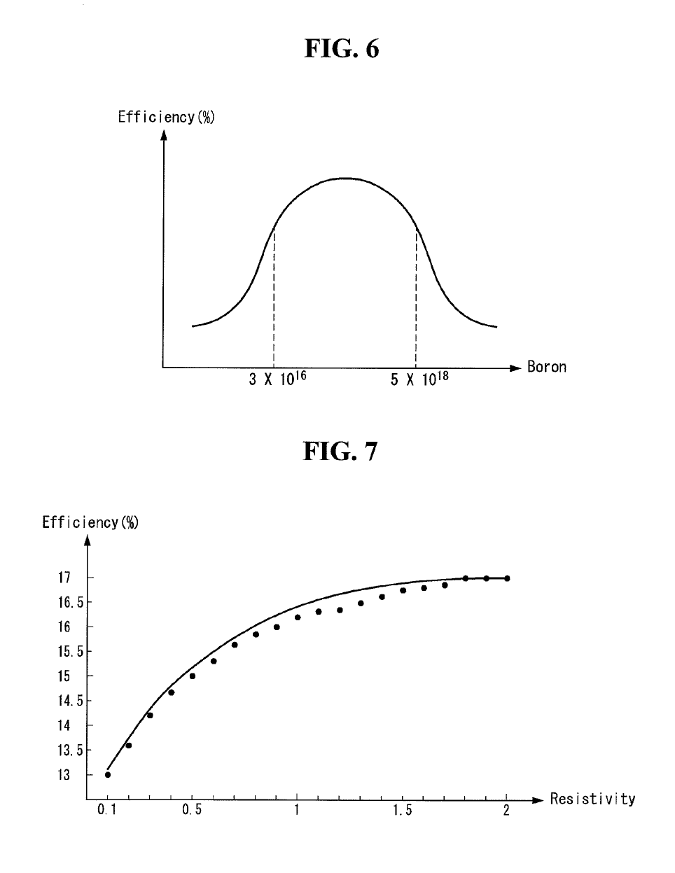

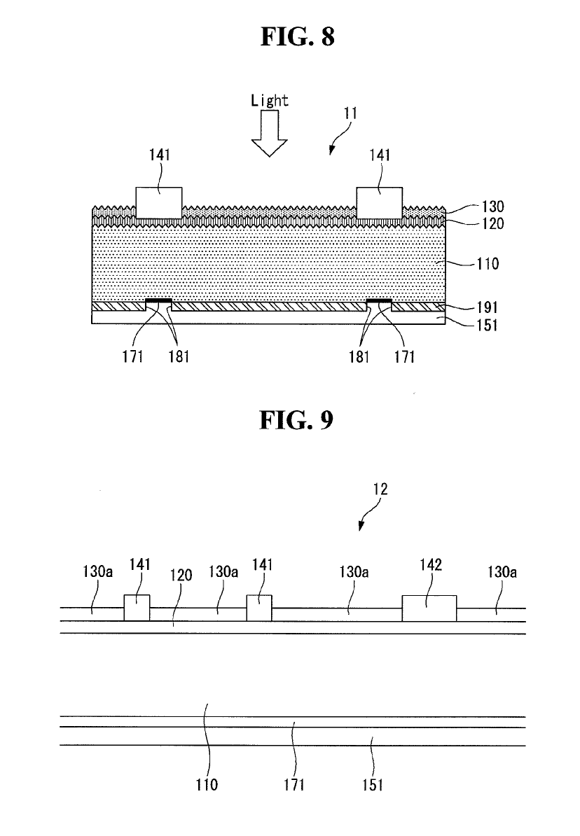

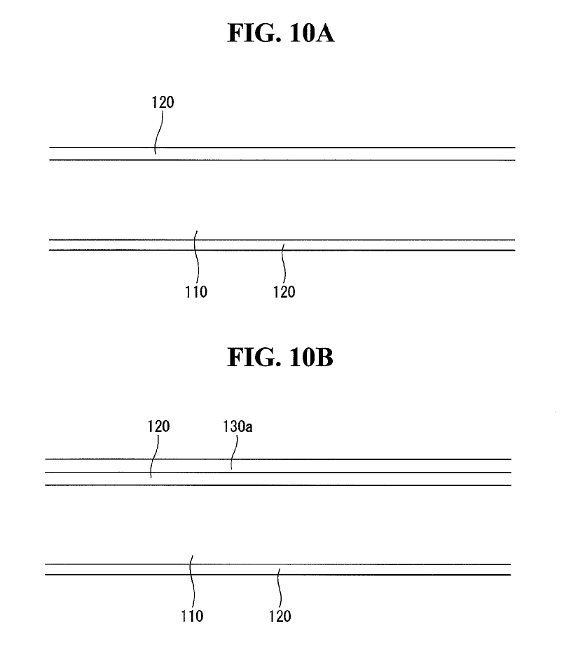

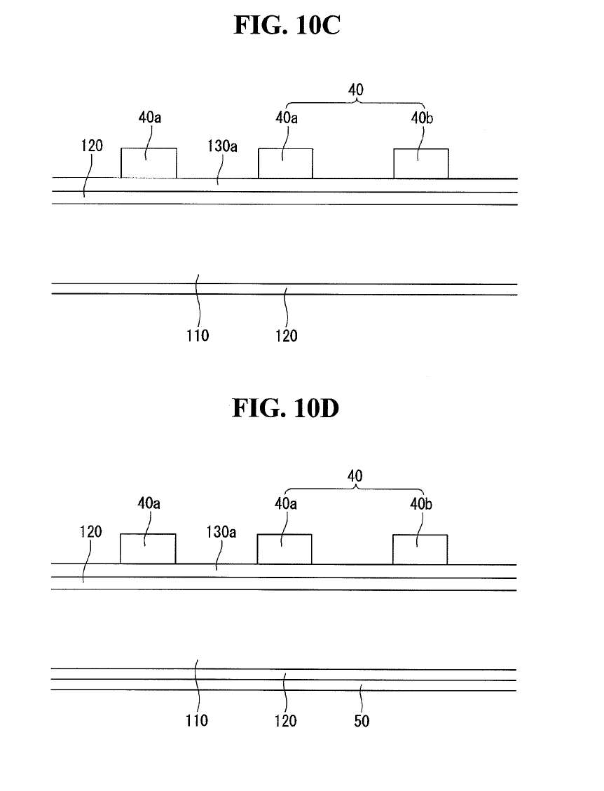

FIG. 1 illustrates a partial perspective view of a solar cell according to an embodiment of the present invention. FIG. 2 illustrates a cross-sectional view of a solar cell along the II-II line shown in FIG. 1. FIG. 3 illustrates a shape example of a textured surface of a substrate according to an embodiment of the present invention. FIG. 4 illustrates density variation of activated impurities according to thickness variation of an emitter region according to an embodiment of the present invention and density variation of activated impurities according to thickness variation of the emitter region according to a comparative example. FIG. 5 is a graph illustrating efficiency variation of a solar cell with respect to bulk lifetime of a substrate. FIG. 6 is a graph illustrating variation of an efficiency of a solar cell as density of boron contained in a substrate is varied and FIG. 7 is a graph illustrating variation of an efficiency of a solar cell as resistivity of a substrate is varied.

Referring to FIG. 1, a solar cell 1 according to an embodiment of the present invention includes a substrate 110, an emitter region 120 disposed on a surface of the substrate 110 on which light is incident (hereinafter, it is referred to as a ‘front surface’), an anti-reflection layer 130 disposed on the emitter region 120, a first electrode unit 140 connected to the emitter region 120, a second electrode 151 on a surface of the substrate 110, the surface being in the opposite of the front surface and without incident light (hereinafter, it is referred to as a ‘rear surface’), and a back surface field (BSF) region 171 disposed at the rear surface of the second electrode 151. The back surface field (BSF) region 171 may be disposed at a location between the substrate 110 and the second electrode 151.

A substrate 110 is a semiconductor substrate made from silicon of a first conductive type such as p-type conductive silicon. In this case, polycrystalline silicon is used, however, single crystal silicon or amorphous silicon may also be used.

In the embodiment, since the substrate 110 has a p-type conductive type, the substrate 110 may have impurity of group III element such as boron (B), gallium (Ga), and indium (In).

However, differently from the above, the substrate 110 may have an n-type conductive type, In this case, the substrate 110 may have impurity of group V element such as phosphorus (P), arsenic (As), and antimony (Sb). Also, in an alternative embodiment, the substrate 110 may also be made from semiconductor materials other than silicon.

The substrate 110 may be manufactured by using a method of melting a silicon raw material and a reactive material together in a furnace and removing impurities from the silicon raw material. Also, the substrate 110 is a polycrystalline silicon substrate of a low purity level. In other words, whereas a wafer from a conventional process has a purity level higher than a 6N level, the purity level of the substrate 110 employed in the embodiment may be lower than 5N, having more impurity than that of the conventional one. For example, the purity level of the substrate 110 may range from 2N to 5N.

The substrate 110 may also be a metallurgical grade silicon substrate. In addition, the substrate 110 may include metallic impurities. In one embodiment, metallurgical grade refers to a grade of purity that is at least three orders of magnitude less than a pure product. In an embodiment of the present invention, metallurgical grade silicon refers to purity of silicon that is about three orders of magnitude less than solar grade silicon. Solar grade silicon may be 99.99999% pure. In one embodiment of the present invention, reference to metallurgical grade silicon may be purity of silicon that is about 3 to 6 magnitudes less than solar grade silicon.

In example embodiments, silicon is extracted from silica in electric furnaces using carbon electrodes at high temperatures. During the process of production, liquid silicon is collected at the bottom of the furnace. When drained and cooled, such silicon may be referred to as metallurgical grade silicon. Metallurgical grade silicon may be obtained from silica using other methods. Such metallurgical grade silicon may be at least 98% pure. A grade of silicon having greater purity may be referred to as upgraded metallurgical grade (UMG) silicon. Such upgraded metallurgical grade silicon may be formed from metallurgical grade silicon by a purification process. One such process may be molten salt electrolysis.

By using the substrate 110 above, a manufacturing cost of the substrate 110 may be reduced and accordingly, a manufacturing cost of the solar cell maybe reduced. The purity level 5N of the substrate 110 means that the silicon content of the substrate 110 is approximately 99.999% (the number of FIG. (or character) 9 is five, 99.999-99.9998%, for example). Put differently, the purity level of 5N means that the substrate 110 has a silicon content of approximately 99.999% grade. When the purity level of the substrate 110 is 7N, it means that the silicon content is of approximately 99.99999% grade.

The front surface of the substrate 110 is a light incident surface and has a textured surface made uneven from a texturing process. Therefore, an area of the incident surface of the substrate 110 increases and reflectivity of light in the upper surface of the substrate 110 is reduced. Also, since absorption of light into the solar cell 1 is increased by incidence and reflectance of light due to the uneven surface, the efficiency of the solar cell 1 is improved.

Each of projections 115 formed on the textured surface has a shape of a random pyramid.

In the embodiment, in most cases, the textured surface of the substrate 110 is made from either a wet etching method or a dry etching method.

In an alternative embodiment, the textured surface of the substrate 110 has a shape as shown in FIG. 3. That is to say, each projection 115a has an irregular shape as the projection 115 of the textured surface shown FIGS. 1 and 2. The end of the projection 115a has a more round shape than that of the projection 115.

In the textured surface of the substrate 110 shown in FIG. 3, a diameter d1 of a bottom surface (largest diameter) of each projection 115a ranges approximately from 100 nm to 500 nm and a height d2 of each projection 115a also ranges approximately from 100 nm to 500 nm.

The textured surface above may be formed by a reaction ion etching (RIE) method which is one of dry etching methods. In this case, as an etching gas, a mixture of SF₆ and O₂ may be used. Therefore, plasma made from a raw gas is generated in a process chamber in which the substrate 101 is placed and the etching gas is then used to etch the substrate 110.

In the mixture of SF₆ and O₂, the fluorine gas (SF₆) has an ion radius shorter than a bond distance between silicon (Si) atoms and therefore, the silicon atoms may easily break the bonds irrespective of a directional face such as (000) and (111), etc. and the silicon etching is made easy. On the other hand, the oxygen gas (O₂) obstructs an etching operation of silicon (Si) as the oxygen gas effects as a mask interfering with an etching process applied for the parts to which oxygen particles are attached.

In this way, due to different etching properties of the fluorine gas (SF₆) and the oxygen gas (O₂), the textured surface is formed on the incident surface of the substrate 110 in the form of the plurality of projections 115 with irregular shapes. In other words, due to difference of etching speeds between surface regions of the substrate 110 to which oxygen particles are attached and surface regions of the substrate 110 to which oxygen particles are not attached, etched surfaces of the substrate 110 becomes the textured surface.

At this time, parts damaged by ions contained in the plasma are removed during the etching process and accordingly, the end of each projection 115a of the textured surface of the substrate 110 becomes round and roundedness of the textured surface increases.

As described above, since damaged parts on the textured surface are removed at the time of forming the textured surface of the substrate 110 before the emitter region 120 is formed, there is no need to employ a process for removing the damaged parts on the textured surface through a wet etching process, etc., after the emitter region 120 is formed, and thus time needed for manufacturing the solar cell 1 is reduced.

The emitter region 120 formed on the substrate 110 is an impurity region equipped with a second conductive type such as an n-type, which is the opposite of a conductive type of the substrate 110, and forms a p-n junction with the substrate 110. Additionally, the substrate 110 has the same purity as the emitter region 120, so that, when the substrate 110 is formed of silicon, the emitter region 120 has the same silicon purity as the substrate 110.

By a built-in potential difference generated due to the p-n junction, a plurality of electron-hole pairs, which are generated by incident light onto the semiconductor substrate 110, are separated into electrons and holes, respectively, and the separated electrons move toward the n-type semiconductor and the separated holes move toward the p-type semiconductor. Thus, when the substrate 110 is of the p-type and the emitter region 120 is of the n-type, the separated holes move toward the substrate 110 and the separated electrons move toward the emitter region 120.

Because the emitter region 120 forms the p-n junction with the substrate 110, when the substrate 110 is of the n-type, then the emitter region 120 is of the p-type, in contrast to the embodiment discussed above, and the separated electrons move toward the substrate 110 and the separated holes move toward the emitter region 120.

Returning to the embodiment, when the emitter region 120 is of the n-type, the emitter region 120 may be formed by doping the substrate 110 with impurities of the group V element such as P, As, Sb, etc., while when the emitter region 120 is of the p-type, the emitter region 120 may be formed by doping the substrate 110 with impurities of the group III element such as B, Ga, In, etc.

Generally, when the impurities are driven into the substrate 110 over solid solubility when the emitter region 120 is formed by diffusion of the impurities into the substrate 110, undissolved impurities in the substrate 110 remain on the surface of the substrate 110 and form a dead layer which extinguishes charges moving to the emitter region 120 and absorbs incident light. For example, when the n-type emitter region 120 is formed by diffusing a POCl₃ gas in the p-type silicon substrate 110, inactive impurities not dissolved inside the substrate 110 form the dead layer by either forming clusters made of phosphorus (P) or forming Si—P structures in which silicon (Si) and phosphorus (P) are combined. Due to the dead layer above, loss of charges occurs as electrons which moved to the emitter region 120 are captured and disappeared or recombined with dangling bonds, and loss of light occurs as incident light from the outside is absorbed in the emitter region 120.

When impurity density at the emitter region 120 is analyzed with reference to FIG. 4, it is found that the density of impurities is reduced as one goes down from the surface of the emitter region 120 to the bottom region of the substrate 110. The Density of impurities is significantly reduced in the vicinity of some particular thickness. At this point, the density of impurities of upper regions around the surface ranging from the surface of the emitter region 120 to the dead layer is higher than that of the remaining region. In this embodiment, the upper regions around the surface including the dead layer are referred to as a high density doped region and the other remaining regions are referred to as a low density doped region.

In the emitter region 120 according to the embodiment, the total density of impurities activated in the high density doped region may range approximately from 4×10²⁰ atoms/cm³ to 6×10²⁰ atoms/cm³ and a depth of the high density doped region, namely a doped thickness, may be less than about 0.03 μm. Also, the total density of impurities activated in the emitter region 120 may range approximately from 1×10¹⁹ atoms/cm³ to 5×10¹⁹ atoms/cm³ and the total thickness of the emitter region 120 may be about 0.25 μm. In this case, the activated impurities correspond to impurities being coupled in a normal way to the lattice structures of silicon (Si) and affecting surface resistance of the emitter region 120. On the other hand, the inactivated impurities correspond to impurities not being coupled to the lattice structures of silicon (Si) and having no actual influence on the surface resistance just like the case when silicon (Si) and the impurity such as phosphorus (P) are combined (Si—P) or the impurities are combined such as P—P combination. Also, the thickness (depth) corresponds to the thickness (depth) measured from the surface of the emitter region 120.

Meanwhile, in the case of a comparative example of a solar cell, the total density of activated impurities in the high density doped region was approximately 3.4×10²⁰ atoms/cm³, a depth of the high density doped region was about 0.04 μm. The total density of impurities at the emitter region was approximately 5.3×10¹⁹ atoms/cm³ and the total thickness of the emitter region was about 0.3 μm.

FIG. 4 illustrates density variation (A) of activated impurities according to thickness variation of an emitter region according to an embodiment of the present invention and density variation (B) of activated impurities according to thickness variation of the emitter region according to a comparative example.

With reference to FIG. 4, it may be known that while the density of activated impurities in a high density doped region (H) is significantly higher in the case of the embodiment than the comparative example, the density of activated impurities in a low density doped region is lower in the case of the embodiment than the comparative example.

Likewise, compared with a solar cell of the comparative example, the total density of activated impurities of the emitter region 120 in the high density doped area (H) has significantly increased, which means that the total density of inactivated impurities has been decreased in the high density doped area (H) as much as the total density of activated impurities has been increased. Therefore, since the density of inactivated impurities causing loss of charges and light is decreased, the efficiency of a solar cell according to the embodiment is increased.

Also, a thickness of the high density doped region (H) of the emitter region 120 according to the present embodiment has been decreased more than a high density doped area (H1) of the emitter region according to a comparative example and the total thickness of the emitter region 120 has also been decreased more than that of the comparative example.

In a normal case, as the density of impurities is increased, mobility of charges is reduced. As shown in the present example, when the high density doping region (H) of the emitter region 120 and the total thickness of the emitter region 120 for impurities are decreased, since mobility of charges moving from the substrate 110 to a first electrode unit 140 through the emitter region 120 is increased, the amount of charges transferred to the first electrode unit 140 may be increased. Therefore, the efficiency of a solar cell 1 may be improved.

In addition, when the density of impurities in the emitter region 120 is increased, contact resistance with the first electrode unit 140 is reduced and thus conductivity of charges is improved. As described above, since the total density of activated impurities of the high density doped region which makes contact with the first electrode unit 140 is increased, the contact resistance between the first electrode unit 140 and the emitter region 120 is reduced. Accordingly, conductivity of charges from the emitter region 120 to the front electrode unit 140 is improved and thus, the efficiency of a solar cell 1 is enhanced still further.

According to the present embodiment, while the total density of activated impurities in the emitter region 120 is increased in the high density doped region, the total density of activated impurities is decreased in the low density doped region. Also, since thicknesses of both the high density doped region and the emitter region 120 are reduced, respectively, loss of charges and light caused by the inactivated impurities is reduced and mobility of charges is improved. Moreover, since the contact resistance between the front electrode unit 140 and the emitter region 120 is reduced, the efficiency of a solar cell 1 is enhanced.

The anti-reflection layer 130 disposed on the emitter region 120 include a silicon nitride (SiNx) layer, a silicon oxide (SiOx) layer, or a silicon oxide-nitride layer. The anti-reflection layer 130 reduces reflectivity of light incident on the solar cell 1 and increases selectivity of a particular wavelength region, improving the efficiency of the solar cell 1.

The refractive index of the anti-reflection layer 130 may be adjusted in such a way that reflectivity of light is reduced and for example, the refractive index may be made smaller than that of the substrate 110. As one example, the anti-reflection layer 130 may have a refractive index ranging approximately from 2 to 3.85.

The anti-reflection layer 130 has a single-layered structure, but multi-layered structure such as a double-layered with different separate refractive indices may also be employed, and in some case, the anti-reflection layer 130 may be removed depending on the needs or desire. For example, in the case of an anti-reflection layer with multi-layered structure, the refractive index of the anti-reflection layer is reduced as the layer is disposed more closely to the substrate 110 and is smaller than that of the substrate 110. In other words, depending on the order of incidence of light from the outside, the refractive index may be increased. In this way, when the refractive indices of the anti-reflection layer with the multi-layered structure are adjusted, since a direction of incident light from the outside is changed in such a direction to reduce reflectivity of light due to the change of the refractive index, reflectivity of the solar cell 1 is reduced.

The first electrode unit 140, as shown in FIGS. 1 and 2, includes a plurality of first electrodes 141 and a plurality of charge collectors 142 (hereinafter, referred to as ‘a plurality of first electrode charge collectors 142) for the first electrodes 141.

The plurality of first electrodes 141 are electrically and physically connected to the emitter region 120 and extend in a predetermined direction nearly in parallel to each other.

The plurality of first electrodes 141 collects charges, e.g., electrons that move to the emitter region 120.

The plurality of first electrode charge collectors 142 extend in a direction intersecting the first electrodes 141 nearly in parallel to each other and are connected electrically and physically to the first electrodes 141 as well as the emitter region 120.

The plurality of first electrode charge collectors 142 are disposed in the same layer as the plurality of first electrodes 141 and are connected to the corresponding first electrodes 141 electrically and physically at the crossing points with the respective first electrodes 141. The plurality of first electrode charge collectors 142 described above collect charges transferred through the plurality of first electrodes 141 and output them to an external device.

The first electrode unit 140 contains a conductive material such as silver (Ag) but at the same time, may contain at least one selected from a group consisting of nickel (Ni), copper (Cu), aluminum (Al), tin (Sn), zinc (Zn), indium (In), titanium (Ti), gold (Au), and a combination thereof or other conductive materials different from the above.

Due to the first electrode unit 140 connected electrically and physically to the emitter region 120, the anti-reflection layer 130 is disposed on the emitter region 120 where the first electrode unit 140 is not disposed.

The second electrode 151 on the rear surface of the substrate 110 is positioned on almost the entire area of the rear surface of the substrate 110.

The second electrode 151 above collects charges moving to the direction of the substrate 110 such as holes.

The second electrode 151 contains at least one conductive material such as aluminum (Al) but in an alternative embodiment, may contain at least one selected from a group consisting of nickel (Ni), copper (Cu), silver (Ag), tin (Sn), zinc (Zn), indium (In), titanium (Ti), gold (Au), and a combination thereof or other conductive materials different from the above.

The back surface field region 171 disposed between the second electrode 151 and the substrate 110 is a region where impurities of the same conductive type as the substrate 110 are doped more heavily than the substrate 110, for example, p+ region.

A potential barrier is formed by an impurity density difference between the substrate 110 and the back surface field region 171, thereby distributing the movement of charges (for example, electrons) to a rear portion of the substrate 110. Accordingly, the back surface field region 171 prevents or reduces the recombination and/or the disappearance of the separated electrons and holes in the rear surface of the substrate 110.

In addition to the structure above, the solar cell 1 may further include a plurality of charge collectors (referred to as ‘a plurality of second electrode charge collectors) for the second electrode 151, which are disposed on the rear surface of the substrate 110.

The plurality of second electrode charge collectors, similar to the plurality of first electrode charge collectors 142, are connected electrically to the second electrode 151 and collect charges transferred from the second electrode 151 and output them to the external device. The second electrode charge contains at least one conductive material such as silver (Ag).

An operation of the solar cell 1 of the structure will be described in detail.

When light irradiated to the solar cell 1 is incident on the substrate 110 of the semiconductor through the anti-reflection layer 13 and the emitter region 120, a plurality of electron-hole pairs are generated in the substrate 110 by light energy based on the incident light.

Further, since a reflection loss of light incident onto the substrate 110 is reduced by the anti-reflection layer 130, an amount of the incident light on the substrate 110 increases.

The electron-hole pairs are separated by the p-n junction of the substrate 110 and the emitter region 120, and the separated electrons move toward the emitter region 120 of the n-type and the separated holes move toward the substrate 110 of the p-type. The electrons that move toward the emitter region 120 are collected by the front electrodes 141 in contact with the emitter portions 120 and then move to the first electrode collectors 142, while the holes that move toward the substrate 110 are collected by the rear electrode 151 through the back surface field region 171. When the front electrodes 141 and the rear electrode 151 are connected with electric wires, current flows therein to thereby enable use of the current for electric power.

Next, a method for manufacturing the substrate 110 of the present embodiment by using a melting process is described.

First, a silicon raw material and a reaction material are put into a furnace and are melted together.

In this case, the silicon raw material may include silica (SiO₂) and the reaction material may include a metallic material.

Preferably, the reaction material may include aluminum (Al). The melting point of aluminum (Al) is approximately 660° C. and the melting point of silicon is approximately 1400° C., the melting point of aluminum (Al) is considerably lower than that of silicon. Therefore, aluminum (Al) effectively absorbs and removes impurities contained in the silicon raw material.

That is to say, when the silicon raw material and the reaction material are melted together, the reaction material such as aluminum (Al) is melted at about 660° C. before the silicon raw material of the mixture of the silicon raw material and the reaction material. Therefore, melted aluminum (Al) first absorbs impurities that are not melted because of the higher melting point than that of aluminum (Al) of the silicon raw material.

When the silicon raw material and the reaction material are melted together, as the temperature of the furnace is increased approximately to 1400° C., silicon (Si) of the silicon raw material melts. At this time, as described earlier, impurities remaining (not melted) in the silicon raw material are absorbed by the melted aluminum (Al).

When the temperature inside the furnace reaches below about 1400° C. as the temperature of the furnace is gradually lowered, the melted silicon (Si) is slowly hardened and silicon (Si) crystal is generated. At the same time, the impurities are maintained in a state where they are absorbed by aluminum (Al) still in the melted state.

At this time, when aluminum (Al) in the melted state is removed, the impurities are also removed together with aluminum (Al) and inside the furnace, only the silicon crystal generated is remained. By using the above silicon (Si) crystal, the polycrystalline silicon substrate 110 is manufactured.

When silicon (Si) crystal is manufactured by using the above method and the substrates 110 are manufactured by using the manufactured silicon (Si), a manufacturing time for substrates 110 is reduced and equipments required for the manufacturing process is also simplified, thereby a manufacturing cost is reduced considerably and a purity level of the substrate 110 is kept approximately below 5N.

Meanwhile, when the substrate 110 is manufactured by using the melting method above, when process conditions are controlled even more precisely, the substrate 110 with a purity level of about 6N may be manufactured.

Although the above example used aluminum as the reaction material, any material which has a lower melting point than that of silicon (Si) would be equally acceptable as the reaction material.

The reaction material may remain in the substrate 110 after refining. In other words, since the substrate 110 refined by using the reaction material may include the reaction material as impurities, the impurities contained in the substrate 110 may be metallic impurities such as aluminum. At this time, the content (amount or density) of the metallic impurities contained in the substrate 110 are varied according to a refining process and the content (amount or density) of metallic impurities contained in the substrate 110 may range approximately from 0.001 to 1.0 ppmw (parts per million by weight). For example, when aluminum (Al) is used as the reaction material, the content (amount or density) of aluminum contained in the substrate 110 may range approximately from 0.001˜1.0 ppmw. In one example, the content (amount or density) of aluminum contained in the substrate 110 may range approximately from 0.001˜0.8 ppmw.

Also, the substrate 110 may include a different kind of impurities such as iron (Fe). For example, the substrate 110 may include iron (Fe) ranging approximately from 0.001˜1.0 ppmw.

In another example, the semiconductor substrate 110 of the solar cell 1 according to this embodiment maybe manufactured by using a gas phase method.

The gas phase method generates a silicon gas by vaporizing silicon and collects generated silicon (Si) gas and grows crystals. When the gas phase method is used, silicon crystals with a purity level more than about 6N and semiconductor substrates based on the crystals may be manufactured.

When the substrate 110 is manufactured by the gas phase method, the manufacture of the substrate 110 with lower content (amount or density) of impurities than that from the melting method described above is possible and the efficiency of a solar cell 1 is improved.

To overcome the problem of the melting method where the substrate 110 with a lower quality than that from the gas phase method is manufactured, in the present embodiment, bulk lifetime of the substrate 110 is increased. For example, the bulk lifetime of the substrate 110 may range approximately from 0.1 μs to 2 μs. In this case, the bulk lifetime of the substrate 110 corresponds to the period from the time when carriers are generated in the semiconductor substrate 110 by incident light to the time when the generated carriers disappear due to recombination, etc.

As shown in FIG. 5, when the bulk lifetime of the substrate 110 is shorter than about 0.1 μs, time needed for the first electrodes 141 and the second electrode 151 to collect the corresponding charges is shortened accordingly and therefore, the efficiency of a solar cell 1 becomes very low.

In general, the bulk lifetime of the substrate 110 is proportional to the purity level of the substrate 110 and, as described earlier, a manufacturing cost is increased to improve the purity level of the substrate 110.

Therefore, to prevent or reduce deterioration of the efficiency of a solar cell 1 while using the melting method which incurs a low manufacturing cost, as described above in the present embodiment, it is advantageous to set the bulk lifetime of the substrate 110 to range approximately from about 0.1 μs to 2 μs.

At this time, the bulk lifetime of the substrate 110 may correspond to the bulk lifetime of the substrate 110 made of a bare silicon wafer.

However, the bulk lifetime of the substrate 110 varies according to chemical passivation treatment of the substrate 110. In other words, when chemical passivation treatment is applied to the substrate 110, the bulk lifetime of the substrate 110 is increased.

For example, when the chemical passivation treatment is applied for the substrate 110, the bulk lifetime of the substrate 110 may be more than about 5 μs. Therefore, when the chemical passivation treatment is applied for the substrate 110 manufactured by the melting method according to the present embodiment, the bulk lifetime of the substrate 110 is increased to about 5 to 15 μs.

In the following, the bulk lifetime of the substrate 110 corresponds to a bulk lifetime of a substrate made of a silicon wafer on which the chemical passivation treatment performed.

When the content (amount or density) of impurities for the conductive type such as boron (B) is too small in the substrate 110, the amount of carriers generated in the substrate 110 are also reduced and the efficiency of the solar cell 1 is reduced. On the other hand, when the content (amount or density) of impurities for the conductive type of the substrate 110 is too much, the total content (amount or density) of impurities of the substrate 110 becomes excessively high, which also makes the efficiency of the solar cell 1 deteriorate.

Therefore, to prevent or reduce the deterioration of the efficiency of the solar cell 1 which uses the substrate 110 manufactured by the melting method, as shown in FIG. 6, in the case of boron (B), density of impurities of the substrate 110 for the conductive type may be determined within a range of about 3×10¹⁶˜5×10¹⁸ atoms/cm³.

Oxygen and carbon contained in the substrate 110 may improve electrical characteristics of the substrate 110. When the content (amount or density) of oxygen and carbon is too much, however, oxygen and carbon effect as impurities and the amount of carriers to be generated may be largely reduced and the bulk lifetime of the substrate 110 may also be considerably reduced. Accordingly, it is advantageous to set the density of oxygen of the substrate 110 to be in a range of about 1×10¹⁸˜1×10¹⁹ atoms/cm³ and the density of carbon of the substrate 110 to be in a range of about 1×10¹⁶˜1×10¹⁹ atoms/cm³.

In what follows, the relationship between resistivity of the substrate 110 and an efficiency of the solar cell 1 with respect to the resistivity is described with reference to FIG. 7.

FIG. 7 is a graph illustrating the relationship between resistivity of a substrate 110 and the efficiency of the solar cell with respect to the resistivity, in the substrate where a purity level is less than 5N, bulk lifetime is 0.1 μs˜2 μs, density of boron is 3×10¹⁶˜5×10¹⁸ atoms/cm³, density of oxygen is 1×10¹⁸˜1×10¹⁹ atoms/cm³, and density of carbon is 1×10¹⁶˜1×10¹⁹ atoms/cm³.

With reference to FIG. 7, when the resistivity of the substrate 110 according to the present embodiment was 0.1 [Ω·cm], the efficiency of the solar cell was approximately 13% and when the resistivity of the substrate 110 was 0.5 [Ω·cm], the efficiency of the solar cell was approximately 15%.

In this way, although the substrate 110 with the purity level less than 5N was used, when the bulk lifetime of the substrate 110 is set to be about 0.1 μs˜2 μs, the density of boron is set to be about 3×10¹⁶˜5×10¹⁸ atoms/cm³, the density of oxygen is set to be about 1×10¹⁸˜1×10¹⁹ atoms/cm³, and the density of carbon is set to be about 1×10¹⁶˜1×10¹⁹ atoms/cm³, approximately 15% of the efficiency for the solar cell was obtained at the resistivity of 0.5 [Ω·cm].

Also, with reference to FIG. 7, when the resistivity of the substrate 110 is approximately more than about 1.8 [Ω·cm], the efficiency of the solar cell 1 was saturated after it reached approximately 17%.

Meanwhile, when the substrate 110 with the purity level of 6N is manufactured by using the melting method and the solar cell 1 is manufactured by the substrate 110, the efficiency of the solar cell 1 is improved further.

In other cases, when the substrate 110 with the purity level ranging from 2N to 5N is used, significant degradation of the efficiency of the solar cell 1 is prevented or reduced.

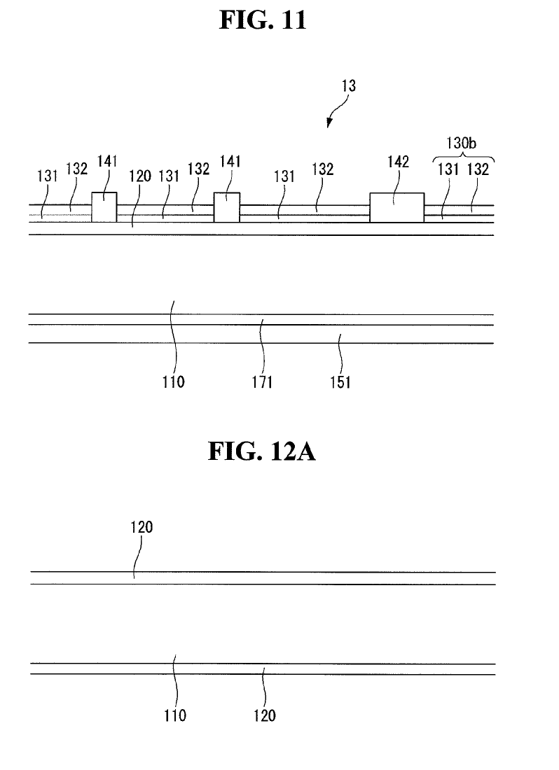

Next, various solar cells according to other embodiments of the present invention are described with reference to FIGS. 8 to 17.

As compared with FIGS. 1 and 2, structural elements having the same functions and structures as those illustrated in FIGS. 1 and 2 are designated by the same reference numerals, and a further description may be briefly made or may be entirely omitted.

First, with reference to FIG. 8, a solar cell 11 according to another embodiment of the present invention is described.

FIG. 8 illustrates a partial cross-sectional view of a solar cell according to another embodiment of the present invention.

As shown in FIG. 8, the solar cell 11, different from FIGS. 1 and 2, further includes a passivation layer 191 on the rear surface of a substrate 110 and a second electrode 151 is disposed on the passivation layer 191.

The passivation layer 191 includes a plurality of openings 181 exposing portions of the substrate 110. Therefore, the second electrode 151 is connected electrically and physically to the substrate 110 through the plurality of openings 181.

The passivation layer 191 changes a defect such as dangling bonds existing in the vicinity of the surface of the substrate 110 into stable bonds, reduces disappearance of charges which have moved to the substrate 110 due to the defect, and redirects the light which has passed through the substrate 110 again to the substrate 110.

Due to the above, a recombination velocity of the charges in the rear surface of the substrate 110 is reduced and reflection at the rear surface is increased. For example, the passivation layer 191 may increase reflection at the rear surface approximately more than 80% and reduces the recombination velocity at the rear surface approximately by 500 cm/s. Therefore, even if a thickness of the substrate 110 is small, a stable photo-electric conversion efficiency is obtained and an efficiency of a solar cell 11 is improved.

In FIG. 8, the passivation layer 191 is made of a single-layered structure, which may have a multi-layered structure made of double layers or triple layers. In an alternative example, the passivation layer 191 is positioned on the front surface of the substrate 110 and prevents or reduces loss of charges moving to the front surface of the substrate 110, the loss being caused by a defect.

As described above, when the passivation layer 191 is positioned directly on the rear surface of the substrate 110, a plurality of back surface field regions 171 are formed where the substrate 110 and the second electrode 151 come into contact with each other.

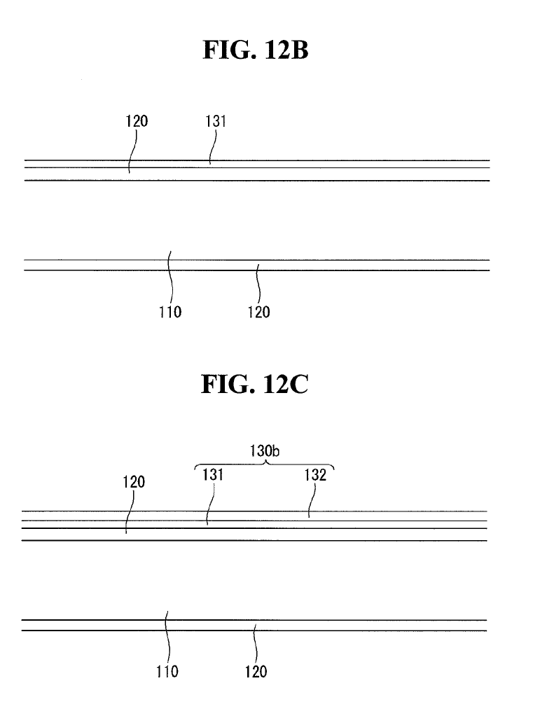

A solar cell 12 shown in FIG. 9, compared with FIGS. 1 and 2, has the same structure except for an anti-reflection layer 130a. In FIG. 9, the substrate 110 does not have a textured surface, as described with reference to FIGS. 1 to 3, but the textured surface may be employed.

FIG. 9 illustrates a partial cross-sectional view of a solar cell according to another embodiment of the present invention.

A solar cell 12 is equipped with an anti-reflection layer 130a including a single layer of silicon nitride (SiNx). The anti-reflection layer 130a of the present embodiment, however, has a varying refractive index depending on its disposition. That is to say, the refractive index increases as a position of anti-reflection layer 130a moves to the emitter region 120 while the refractive index decreases as the position of the anti-reflection layer 130a moves to the incident surface of the anti-reflection layer 130a. Namely, the refractive index in the vicinity of a boundary between the emitter region 120 and the anti-reflection layer 130a ranges approximately from 2.3 to 2.9. The refractive index is gradually decreased as the position of the anti-reflection layer 130a moves to the incident surface of the substrate 110 and the refractive index in the vicinity of the surface of the anti-reflection layer 130a, which is exposed to the outside, ranges approximately from 1.7 to 2.2. In an alternative embodiment, the refractive index of the anti-reflection layer 130a may be changed in a non-linear manner. In other words, the refractive index in the vicinity of a boundary between the emitter region 120 and the anti-reflection layer 130a ranges approximately from 2.3 to 2.9 and the refractive index in the vicinity of the surface of the anti-reflection layer 130a, which is exposed to the outside, range approximately from 1.7 to 2.2. However, change of the refractive index in the vicinity of a boundary between the emitter region 120 and the anti-reflection layer 130a and in the vicinity of the surface of the anti-reflection layer 130a, which is exposed to the outside, may reveal a nonlinear pattern.

Since the refractive index in the vicinity of the emitter region 120 on the surface of the substrate 110 is higher than that of the opposite side, the bottom surface of the anti-reflection layer 130a has an excellent passivation effect whereas the upper surface of the anti-reflection layer 130a has an excellent effect for preventing or reducing light reflection. In this way, as the anti-reflection layer 130a made of a single layer is formed, time and a cost for manufacturing the anti-reflection layer 130a is reduced and accordingly, time and cost for manufacturing the solar cell 12 is reduced.

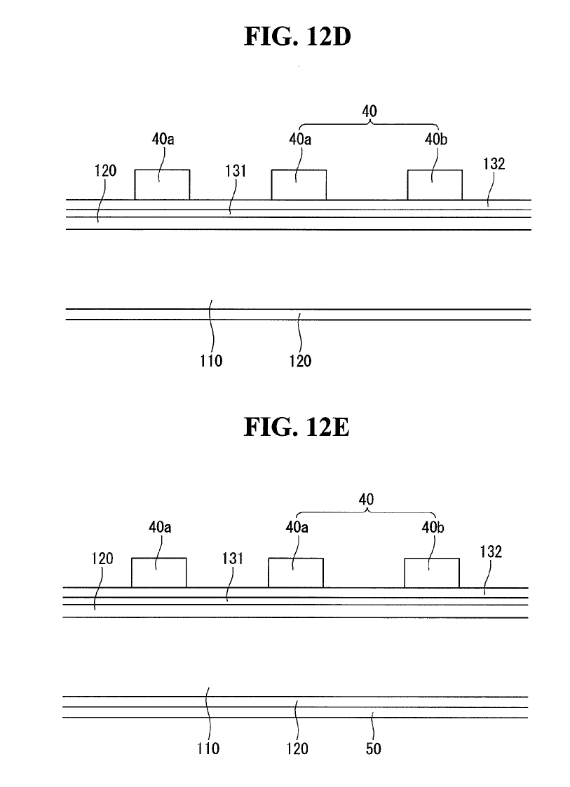

Next, with reference to FIGS. 10A to 10D, a method for manufacturing the solar cell 12 according to the present embodiment is described.

FIGS. 10A to 10D are cross-sectional views sequentially illustrating a method for manufacturing the solar cell shown in FIG. 9.

First, as shown in FIG. 10A, by applying heat treatment to a material, for example POCl₃ or H₃PO₄, containing impurities of a group V element such as phosphorus (P), arsenic (As), and antimony (Sb), in a high temperature and driven the impurities of the group V element into the substrate 110 made of p-type polycrystalline silicon manufactured by a melting method, an emitter region 120 of an n-type is formed at the entire surface of the substrate 110, namely a front surface, a rear surface, and the both sides thereof.

When the substrate 110 of the p-type contains impurities of boron (B), the substrate 110 may contain boron with density ranging approximately from 3×10¹⁶ atoms/cm³ to 5×10¹⁶ atoms/cm³.

Different from the present embodiment, when the substrate 110 is an n-type, by applying heat treatment to a material, for example B₂H₆ containing impurities of a group III element, in a high temperature or depositing the material, an emitter region of a p-type may be formed in the substrate 110. Next, phosphorous silicate glass (PSG) or boron silicate glass (BSG) generated during the diffusing of the p-type or n-type impurities into the substrate 110 are removed through an etching process.

If necessary, before the forming of the emitter region 120, a texturing process is applied to the front surface of the substrate 110 and a textured surface which is an uneven surface may be formed. At this time, depending on a kind of the substrate 110, the surface is textured by using base solution such as KOH or NaOH or acid solution such as HF or HNO₃ or the surface may also be textured by using a dry etching method such as a reactive ion etching method.

Next, as shown in FIG. 10B, an anti-reflection layer 130a made of silicon nitride (SiNx) is formed on the emitter region 120 disposed in the direction of the incident surface of the substrate 110. In this case, a refractive index of the anti-reflection layer 130a ranges approximately from 2.3 to 2.9 in the vicinity of the bottom surface and the refractive index corresponds to about 1.7 to 2.2 in the vicinity of the upper surface. During the formation of the anti-reflection layer 130a, change of the refractive index is implemented by controlling the injection of ammonia gas (NH₃) and silane gas (SiH₄), and thereby the corresponding portion has a desired refractive index. For example, when a portion of a high refractive index is formed in the anti-reflection layer 130a, supply of ammonia gas (NH₃) is considerably reduced compared when a portion of a low refractive index is formed, increasing the refractive index.

At this point, the anti-reflection layer 130a ranges approximately from 70 nm to 90 nm.

Next, as shown in FIG. 10C, after a first electrode unit paste including silver (Ag) is applied to a desired region by using a screen printing method and dried at a temperature of 170° C., thereby forming a first electrode unit pattern 40. In this case, the first electrode unit pattern 40 includes a first electrode pattern 40a and a first electrode charge collector pattern 40b.

The first electrode unit paste may include, instead of silver (Ag), at least one from a group consisting of nickel (Ni), copper (Cu), aluminum (Al), tin (Sn), zinc (Zn), indium (In), titanium (Ti), gold (Au) and a combination thereof.

Next, as shown in FIG. 10D, after a second electrode paste including aluminum (Al) is applied and dried to the corresponding parts of the rear surface of the substrate 110 by using a screen printing method, a second electrode pattern 50 is formed.

The second electrode unit paste may include, instead of aluminum (Al), at least one from a group consisting of nickel (Ni), copper (Cu), silver (Ag), tin (Sn), zinc (Zn), indium (In), titanium (Ti), gold (Au) and a combination thereof.

The order of forming the first electrode pattern 40 and the second electrode pattern 50 may be changed.

Next, the substrate 110 equipped with the first electrode unit pattern 40 and the second electrode pattern 50 undergoes a firing process at a temperature of about 750° C. to 800° C., forming a plurality of first electrodes 141, a plurality of first electrode charge collectors 142, a second electrode 151, and a back surface field region 171.

In other words, when a heat treatment is applied, plumbum (lead) (Pb) contained in the first electrode pattern 40 helps the first electrode pattern 40 penetrate the anti-reflection layer 130a around the contact area. According to the above, the plurality of first electrodes 141 and the plurality of first electrode charge collectors 142 contacting with the emitter region 120 are formed to complete the first electrode unit 140. At this time, the first electrode pattern 40a of the first electrode unit pattern 40 becomes the plurality of first electrodes 141 and a first electrode charge collector pattern 40b becomes the plurality of first electrode charge collectors.

The second electrode 151 connected electrically and physically to the substrate 110 is formed by the heat treatment, and aluminum (Al) contained in the second electrode 151 is diffused into the substrate 110 contacting the second electrode 151, forming the back surface field region 171 between the second electrode 151 and the substrate 110.

At this point, aluminum (Al) is driven to or over the emitter region 120 disposed in the rear surface of the substrate 110, becoming the back surface field region 171. The back surface field region 171 has the same conductive type (e.g., a p-type) as the substrate 110 and density of impurities of the back surface field region 171 is higher than that of the substrate 110, so as to have a p⁺-type.

Next, an edge isolation is carried out by using laser beams to remove the emitter region 120 formed in the sides of the substrate 110. Thereby, the emitter region 120 formed in the front surface of the substrate 110 and the emitter region 120 formed in the rear surface of the substrate 110 are separately electrically, thereby completing the solar cell 12 (FIG. 9).

As described above, since the refractive index of the anti-reflection layer 130a is varied according to the location, the forming of the anti-reflection layer 130a with a passivation effect is possible, an efficiency of the solar cell 12 is improved.

Also, a solar cell 13 shown in FIG. 11, different from FIGS. 1 and 2, is equipped with an anti-reflection layer with a double-layered structure. In FIG. 11, although the substrate 110 does not have a textured surface, as described earlier with reference to FIGS. 1 to 3, the substrate 110 may have a textured surface.

FIG. 11 illustrates a partial cross-sectional view of a solar cell according to another embodiment of the present invention.

An anti-reflection layer 130b of the present embodiment is equipped with a first film 131 disposed on the emitter region 120 and a second film 132 disposed on the first film 131. The total thickness of the anti-reflection layer 130b ranges approximately from 80 nm to 120 nm.

The first film 131 is made of silicon nitride (SiNx) with a thickness of about 30 nm to 50 nm and has a refractive index of about 2.3 to 2.9.

The first film 131 exhibits a passivation effect which renders a defect such as dangling bonds existing on the surface of the substrate 110 into stable bonds, reduces disappearance of charges which move in the direction of the emitter region 120, by recombining with unstable bonds, and reduces reflectivity of light incident on the substrate 110.

When the refractive index of the first film 131 is smaller than a lower limit (about 2.3), reflection of light is performed well and thereby a function as an anti-reflection layer is not carried out properly, and the passivation effect is deteriorated and thus an efficiency of a solar cell 13 is reduced. On the contrary, when the refractive index of the first film 131 exceeds an upper limit (about 2.8), incident light is absorbed within the first film itself and thus invokes a problem which reduces the photo-electrical conversion efficiency of the substrate 110.

When the thickness of the first film 131 is below a lower limit (about 30 nm), a function as an anti-reflection layer is not carried out properly and when the thickness thereof exceeds a upper limit (50 nm), since amount of light absorbed in the first film 131 is increased and the thickness is also unnecessarily increased, a problem of increasing a manufacturing cost and a process time takes place.

The second film 132 exists only on the first film 131 and is made of silicon nitride in the same as the first film 131. The second film 132 has a thickness of about 50 nm to 70 nm and a refractive index of about 1.7 to 2.2.

The second film 132, together with the first film 131, reduces reflectivity of light incident in the direction of the substrate 110, thereby increasing the amount of light absorbed by the substrate 110. Also, due to hydrogen (H) contained in silicon nitride (SiNx) of the second film 132, the passivation effect for unstable bonds is still further enhanced in the second film 132.

As described above, since the refractive index of the second film 132 is smaller than that of the first film 131, the functionality of the anti-reflection layer is more enhanced than the first film 131 but the passivation effect is reduced.

Further, change of the refractive index from the first film 131 to the second film 132 is decreased in an irregular (or abrupt) fashion.

When the refractive index of the second film 132 is smaller than a lower limit (about 1.7), reflection of light is performed well and thus, a function as an anti-reflection layer is not carried out properly. When the refractive index of the second film 132 exceeds an upper limit (about 2.2), incident light is absorbed within the second film 132 itself and thus invokes a problem which reduces the photo-electrical conversion efficiency of the substrate 110.

When the thickness of the second film 132 is below a lower limit (about 50 nm), a function as the anti-reflection layer is not carried out properly; when the thickness thereof exceeds a upper limit (70 nm), a problem of light being absorbed in the second film 132 takes place.

Therefore, due to the anti-reflection layer 130b including the first film 131 with the passivation effect in most cases and the second film 132 with an anti-reflection effect in most cases, loss of charges is reduced and amount of incident light is increased, therefore, an efficiency of the solar cell 13 is improved. Due to the above, even when the polycrystalline silicon substrate 110 manufactured by using the gas phase method or the melting method or the substrate 110 with a purity level less than about 5N is used, the efficiency of the solar cell 13 is note reduced.

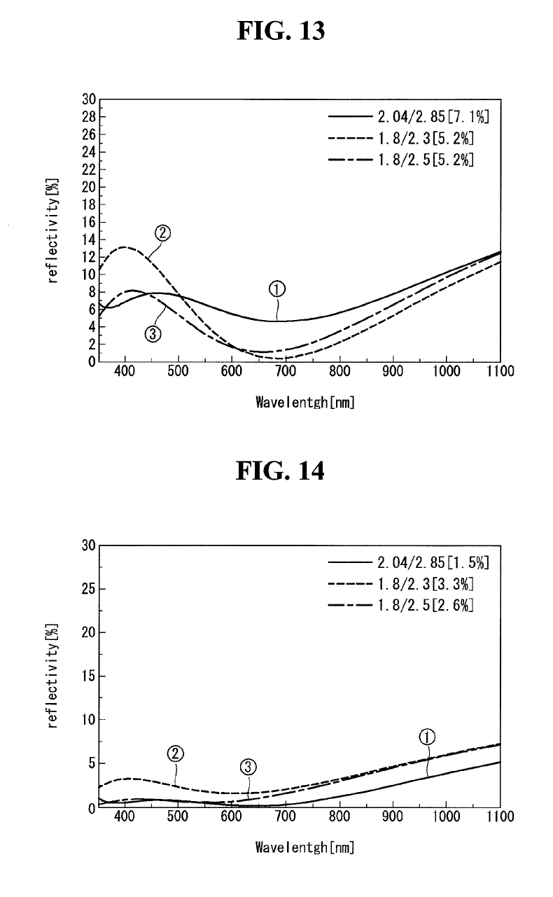

Next, with reference to FIGS. 12A to 12E, a method for manufacturing the solar cell 13 according to the present embodiment is described.

FIGS. 12A to 12E are cross-sectional views sequentially illustrating a method for manufacturing the solar cell shown in FIG. 11.

A method for manufacturing the solar cell 13, compared with the method for manufacturing the solar cell 12 illustrated in FIGS. 10A to 10D, differs only in manufacturing an anti-reflection layer 130a and is the same for manufacturing other constituent elements; therefore, detailed descriptions for the same parts are not provided.

In other words, as shown in FIG. 10A, after an emitter region 120 is formed on a substrate 110 (FIG. 12A), by using a chemical vapor deposition (CVD) method such as a plasma enhanced chemical vapor deposition (PECVD) method in the atmosphere of hydrogen, a first film 131 is formed by depositing silicon nitride (SiNx) on a front surface of the substrate 110 as shown in FIG. 12B. At this time, a thickness of the first film 131 to be formed becomes about 30 nm to 50 nm.

A gas supplied to a chamber to form the first film 131 may be nitrogen, hydrogen, silane (SiH₄), and ammonia (NH₃) gas. Depending on situations, ammonia (NH₃) need not be supplied.

Generally, when a lower film with a high refractive index made of silicon nitride (SiNx) and an upper film with a low refractive index made of silicon oxide (SiOx) were formed, the lower film had a thickness of about 70 nm to 80 nm and the upper film had a thickness of about 90 nm to 100 nm. Thereby, since to secure a uniform refractive index is difficult and process repeatability showing the same characteristics every process is low, the forming of the film with the high refractive index is difficult, and thereby as the thicknesses of the films to be formed becomes large, film characteristics get worse.

However, in the present embodiment, since the thickness of the first film 131 with the high refractive index ranges approximately from 30 nm to 50 nm, which is a significantly reduced value compared with the thickness of 90 nm to 100 nm, the forming of the first film 131 with the high refractive index becomes easy and characteristics of the formed first film 131 is also improved. Also, as the thickness of the anti-reflection layer is increased, amount of light absorbed from the anti-reflection layer is increased. However, since the thickness of the first film 131 is reduced according to the present embodiment, amount of light absorbed in the first film 131 is reduced more than the amount absorbed in a normal lower anti-reflection layer, an efficiency of the solar cell 13 is improved.

Next, as shown in FIG. 12C, in the atmosphere of hydrogen, silicon nitride (SiNx) is deposited on the first film 131 by using a chemical vapor deposition (CVD) method, thereby to form a second film 132. Due to the above, an anti-reflection layer 130b made of first and second films 131 and 132 is completed. As in the case of the first film 131, a gas supplied to a chamber to form the second film 132 may be a nitrogen gas, a hydrogen gas, a silane (SiH₄) gas, and an ammonia (NH₃) gas.

As described above, since the first and second films 131 and 132 are made from the same material, that is, silicon nitride (SiNx), the first and second films 131 and 132 are formed sequentially to have different refractive indices and thicknesses in the same chamber. That is to say, since the kind of material injected into the chamber to form the first and second films 131 and 132 is the same, the first and second films 131 and 132 are formed sequentially by changing process conditions. Since the refractive index is increased as the content (amount or density) of hydrogen (H) is high and the refractive index is decreased as the content (amount or density) of nitrogen (N) is high, the supplying of hydrogen and nitrogen is controlled according to the refractive index of the first and second films 131 and 132. Also, according to thicknesses of the first and second films 131 and 132, a process time is controlled. At this time, as the supplement of hydrogen (H) becomes large, defect such as dangling bonds is reduced due to silicon (Si) and hydrogen (H), thereby to improve the passivation effect.

On the other hand, when the first and second films are formed by using different materials in the same chamber, inconvenience is anticipated in changing the environment of the chamber to form the second film after the first film is formed. In addition, when the first and second films are to be formed by using two different chambers, a manufacturing cost is largely increased due to the number of chambers and a manufacturing time is also increased since the substrate should be moved to the corresponding chamber.

Therefore, when the first and second films 131 and 132 are formed sequentially according to the present embodiment, since inconvenience changing the chamber or the environment of the chamber is solved, the manufacturing time is reduced and a manufacturing process becomes simple. Also, since only one chamber is employed, the manufacturing cost is significantly reduced compared to the case where two chambers should be employed.

Next, as described with reference to FIGS. 12C and 12D, a front electrode unit pattern 40 is formed on the anti-reflection layer 130b (FIG. 12D) and a rear electrode pattern 50 is formed on the rear surface of the substrate 110 (FIG. 12E). Then, after a heat treatment, a plurality of first electrodes 141 and a plurality of first electrode charge collectors 142 contacting electrically and physically with the emitter region 120 are formed and a second electrode 151 contacting electrically and physically with the substrate 110 and a back surface field region 171 between the second electrodes 151 and the substrate 110 are formed, completing the solar cell 13 (FIG. 11).

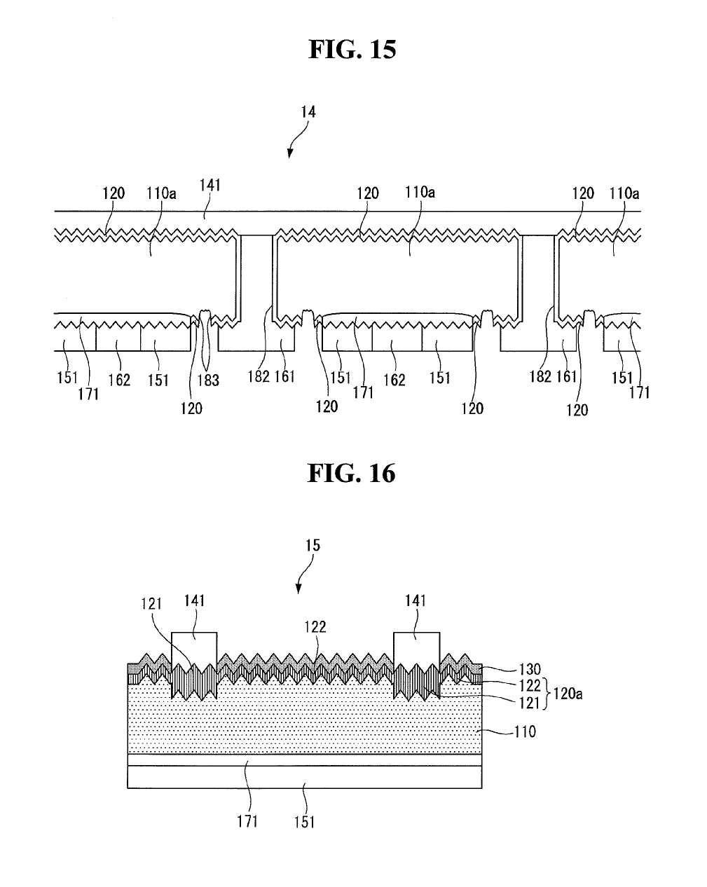

As described above, when the anti-reflection layer 130a including the first and second film 131 and 132 is formed by the same material according to the embodiment of the present invention, an anti-reflection efficiency is examined with reference to FIGS. 13 and 14.

FIGS. 13 and 14 are graphs illustrating reflectivity of light due to the first film and the second film respectively according to the embodiment of the present invention with respect to a wavelength of light. That is, FIG. 13 is a graph illustrating the reflectivity of light with respect to the wavelength of light before forming the front electrode unit and the rear electrode and FIG. 14 is a graph illustrating the reflectivity of light with respect to the wavelength of light after forming the front electrode unit and the rear electrode.

In the FIGS. 13 and 14, first and second graphs \textcircled{1} and \textcircled{2} correspond to graphs of first and second comparative examples where the first and second films of silicon nitride are formed by using a conventional method. A third graph \textcircled{3} corresponds to a graph of the embodiment where the first and second films of silicon nitride are formed according to the embodiment.

In the first comparative example, a refractive index of the second film which is an upper film was 2.04 and a refractive index of the first film which is a lower film was 2.85. In the second comparative example, a refractive index of the second film which is an upper film was 1.08 and a refractive index of the first film which is a lower film was 2.3. Also, in the embodiment, a refractive index of the second film was 1.8 while a refractive index of the first film was 2.5.

Based on the graphs illustrated in FIG. 13, in the case of the first comparative example, average reflectivity across the entire wavelength of light was about 7.1% and in the case of the second comparative example, average reflectivity across the entire wavelength of light was about 5.2%. Also, based on the graphs illustrated in FIG. 13, in the case of the first comparative example, average reflectivity across the entire wavelength of light was about 1.5% and in the case of the second comparative example, average reflectivity across the entire wavelength of light was about 3.3%.

Compared to the above, in the case of the present embodiment, based on the graphs illustrated in FIG. 14, average reflectivity across the entire wavelength of light was about 5.2% and based on the graphs of FIG. 14, reflectivity of light was about 2.6%.

As described above, according to the present embodiment, when the first film is set to be about 2.5 and the second film about 1.8, it may be known that reflectivity of light is decreased.

Also, as shown in FIGS. 13 and 14, when a wavelength (a short wavelength) of light is short below about 700 nm, it may be known that reflectivity of light is considerably reduced. Therefore, the anti-reflection layer 130b according to the embodiment is more effective for preventing or reducing reflection of light with the short wavelength than the light with a long wavelength. Usually, a distance that a minority carrier generated by the long wavelength absorbed in the substrate 110 (hereinafter, it is referred to as ‘a long wavelength minority carrier’) moves to the first electrode unit 140 (namely, bulk lifetime of minority carrier) is much longer than the distance that a minority carrier generated by the short wavelength (hereinafter, it is referred to as ‘a short wavelength minority carrier’) moves to the first electrode unit 140.

When the solar cell 13 is manufactured by using the substrate 110 with a purity level less than 5N manufactured by the melting method, since the bulk lifetime of minority carriers (i.e., electrons) is very short, ranging approximately from 0.1 μs to 2 μs, and thereby large amount of the long wavelength minority carriers is not transferred to the first electrode unit 140 normally and disappears during movement, while most of the short wavelength minority carriers are transferred to the first electrode unit 140 and normally are outputted. After all, when a solar cell is manufactured by using a substrate with the purity level less than that of a substrate manufactured by the gas phase method, the improvement of an absorption efficiency (an anti-reflection efficiency) of light with the short wavelength has more influence on the efficiency of the solar cell rather than the improvement of an absorption efficiency of light with the long wavelength. Therefore, in the case of using the anti-reflection layer 130b of the embodiment, an anti-reflection effect from light with the short wavelength is better than that from light with the long wavelength, it is still more effective for a solar cell that uses a substrate manufactured by the melting method, a substrate with the purity level less than 5N, or a metallurgical silicon substrate.

In what follows, solar cells according to other embodiments of the present invention are described with respect to FIGS. 15 to 17.

FIGS. 15 to 17 illustrate partial cross-sectional views of various solar cells according to other embodiments of the present invention.

A solar cell 14 shown in FIG. 15 includes a substrate 110a, an emitter region 120 and an anti-reflection layer positioned on the substrate 110a, a plurality of first electrodes 141 connected to the emitter region 120, a second electrode 151 connected to the substrate 110a, a plurality of first electrode charge collectors 161 electrically connected to the plurality of the first electrodes 141, a plurality of second electrode charge collectors 162 electrically connected to the second electrode 151, and a back surface field region 171 positioned between the second electrode 151 and the substrate 110a. The solar cell 14 having the above structure may include a passivation layer to improve an efficiency on at least one of the front surface and the rear surface of the substrate 110a.

In the solar cell 14 of the embodiment, however, the substrate 110a is equipped with a plurality of through holes 182.

The plurality of through holes 182 are formed on regions of the substrate 110a where the plurality of first electrodes 141 and the plurality of first electrode charge collectors 161 intersect. At least one of the plurality of first electrodes 141 and the plurality of first electrode charge collectors 161 is extended to either the front surface or the rear surface of the substrate 110a through the plurality of through holes 182. Thus, the plurality of first electrodes 141 and the plurality of first electrode charge collectors 161 disposed on the opposite surface are connected to each other. Accordingly, through the plurality of through holes 182, the plurality of first electrodes 141 and the plurality of first electrode charge collectors 161 are connected electrically and physically.

Due to the above, since the first electrode charge collectors 161 are disposed in the rear surface of the substrate 110a on which light is not incident, a light receiving surface of the solar cell 14 is increased. Therefore, short current (Jsc) of the solar cell 14 is increased.

Accordingly, when the substrate 110a of the solar cell 14 is manufactured by the aforementioned melting method, the short current is reduced than a substrate manufactured by the gas phase method and an efficiency of the solar cell 14 tends to be reduced. This is because a silicon substrate manufactured by the melting method contains more impurities than that manufactured by the gas phase method.

As described above, since the short current is increased as the light receiving surface of the solar cell 14 is increased, the efficiency of the solar cell 14 is not degraded even in the case of using the substrate 110a manufactured by the melting method. At the same time, when the substrate 110a with a purity level less than 5N or of a metallurgical grade is used, degradation of the efficiency of the solar cell 14 is prevented or reduced.

As shown in FIG. 15, the emitter region 120 is disposed inside through holes 182 and in portions of the rear surface of the substrate 110a as well as the front surface of the substrate 110a. Therefore, an exposure portion which exposes a portion of the edge of the front surface is formed in the anti-reflection layer 130 and the emitter region 120 disposed below the anti-reflection layer 130. Therefore, the emitter region 120 formed in the front surface of the substrate 110 and the emitter region 120 formed in the rear surface of the substrate 110 are separated electrically from each other by the exposure portion.

The plurality of first electrode charge collectors 161 disposed on the rear surface of the substrate 110a is made from at least one conductive material. The plurality of first electrode charge collectors 161 extend nearly parallel in a direction of intersecting the plurality of first electrodes 141 disposed on the front surface of the substrate 110a and thus have a shape of stripes. Accordingly, as described earlier, the plurality of through holes 182 are formed in regions where the plurality of first electrodes 141 and the plurality of first electrode charge collectors 161 intersect each other.

The rear electrode 151 disposed on the rear surface of the substrate 110a is separated electrically from the neighboring first electrode charge collectors 161 by a plurality of exposing portions 183. The plurality of exposing portions 183 are formed in the emitter region 120 disposed on the rear surface of the substrate 110a to expose portions of the rear surface of the substrate 110a and are formed around the plurality of first electrode charge collectors 161.

The plurality of second electrode charge collectors 162 positioned on the rear surface of the substrate 110a are connected to the rear electrode 151 electrically and physically and extend nearly parallel to the first electrode charge collectors 161. The plurality of second electrode charge collectors 162 collects charges transferred from the rear electrode 151 such as holes and output them to an external device.

A solar cell 15 shown in FIG. 16, compared with the solar cell 1 illustrated in FIGS. 1 and 2, has differences as follows.

In the solar cell 15 shown in FIG. 16, an emitter region 120a has a selective emitter structure equipped with a first part 121 and a second part 122 having a different thickness from each other depending on a location. At this time, since a thickness of the first part 121 is larger than that of the second part 122 and due to the difference in thickness, density of impurities of the first part 121 and the second part 122 is also different from each other, density of impurities in the first part 121 is higher than that of the second part 122. For example, the first part 121 may be n⁺⁺ region while the second part 122 may be either n⁺ or n region.

The emitter region 120a is formed by first forming an emitter region with high density on the front surface of the substrate 110a and then removing a part of the emitter region in a selective manner, or applying the operation of impurity doping to the first part 121 and the second part 122 separately by using a mask.

The first part 121 corresponds to a region that contacts the plurality of first electrodes 141 [and the first electrode charge collectors] and the remaining part is a second part 122. Therefore, since the first electrodes 141 (and the first electrode charge collectors) are in contact with the emitter region 120a by the first part 121 whose density of impurities is higher than that of the second part 122, contact resistance between the first part 121 and the first electrodes 141 (and the first electrode charge collectors) of the emitter region 120a is reduced and thus an charge transfer rate (or an charge transfer efficiency) is improved and an efficiency of the solar cell 15 is improved. Also, since excessive impurities are not allowed to exist inside the substrate 110 as density of impurities is lowered in the second part 122 of the emitter region 120a disposed in the substrate 110, deterioration of lifetime of the solar cell 15 is prevented or reduced.

Since the efficiency of the solar cell 15 is improved due to the selective emitter structure, even if the substrate 110 is a polycrystalline silicon substrate manufactured by the melting method as well as the gas phase method, a substrate with a purity level less than about 5N, or a substrate of a metallurgical grade, the efficiency of the solar cell 15 is not degraded.

A solar cell 16 shown in FIG. 17 corresponds to a solar cell having a rear surface junction structure where a light receiving surface of the solar cell 16 is increased by disposing first electrodes on a rear surface of the substrate 110 where no light is incident, not on a front surface of the substrate 110 which is a light receiving surface.

Therefore, the solar cell 16 of FIG. 17 has a plurality of emitter regions 120b and a plurality of back surface field regions 171b extending parallel to each other on the rear surface of the substrate 110. Due to the above, in the rear surface of the substrate 110, the emitter regions 120b and the back surface field regions 171b are positioned alternately and the neighboring emitter region 120b and the back surface field region 171b are separated from each other.

As described above, the plurality of emitter regions 120b corresponds to impurity regions doped by impurities of a conductive type opposite to the substrate 110. Similarly, the plurality of back surface field regions 171b corresponds to impurity regions doped by impurities of the same conductive type as the substrate 110 with higher density than that of substrate 110.

The solar cell 16 shown in FIG. 17 is equipped with a passivation layer 191, being disposed in the rear surface of the substrate 110 and exposing parts of the emitter regions 120b and parts of the back surface field regions 171b through a plurality of openings 181.

Therefore, a plurality of first electrodes 141a is connected electrically and physically to the plurality of emitter regions 120b through the plurality of openings 181. A plurality of second electrodes 151 are connected electrically and physically to the plurality of back surface field regions 171b through the plurality of openings 181. In an alternative example, the solar cell 16 may include a front surface field region positioned on a light receiving surface, that is, a front surface of the solar cell 16, and the front surface field region functions as the back surface field regions 171b In this case, the front surface field region disposed on the front surface of the substrate 110 corresponds to an impurity region which contains impurities of the same conductive type as the substrate 110 and has density higher than that of the substrate 110, preventing or reducing electrons and holes from recombination in the vicinity of the light receiving surface of the substrate 110.

As shown in FIG. 17, since the plurality of first electrodes 141a and the plurality of back surface field regions 171b disposed on the rear surface of the substrate 110 are located respectively on the separate planes which have a height difference from each other, they are separated from each other in a vertical direction by a predetermined distance (a predetermined gap). In other words, the plurality of first electrodes 141a and the plurality of back surface field regions 171b are positioned on planes different from each other.

Therefore, since The first electrodes 141a and the back surface field regions 171b are separated from each other in a horizontal and the vertical direction, a butting phenomenon where current flows through the neighboring first electrodes 141a and back surface field regions 171b is prevented or reduced and the efficiency of the solar cell 16 is improved.

As described above, since the first electrodes 141a (and the first electrode charge collectors) which reduces a light receiving area of the substrate 110 are disposed in the rear surface of the substrate 110, the light receiving area of the substrate 110 is increased and the efficiency of the solar cell 16 is improved. Therefore, even if the substrate 110 is a substrate manufactured by the melting method as well as the gas phase method, a substrate with a purity level less than about 5N, or a substrate with a metallurgical grade is used, the efficiency of the solar cell 16 is not reduced.

Even though each solar cell 1 or 11-16 according to various embodiments may be used individually, for more efficient use, a plurality of solar cells with the same structure are connected electrically and form a solar cell module.

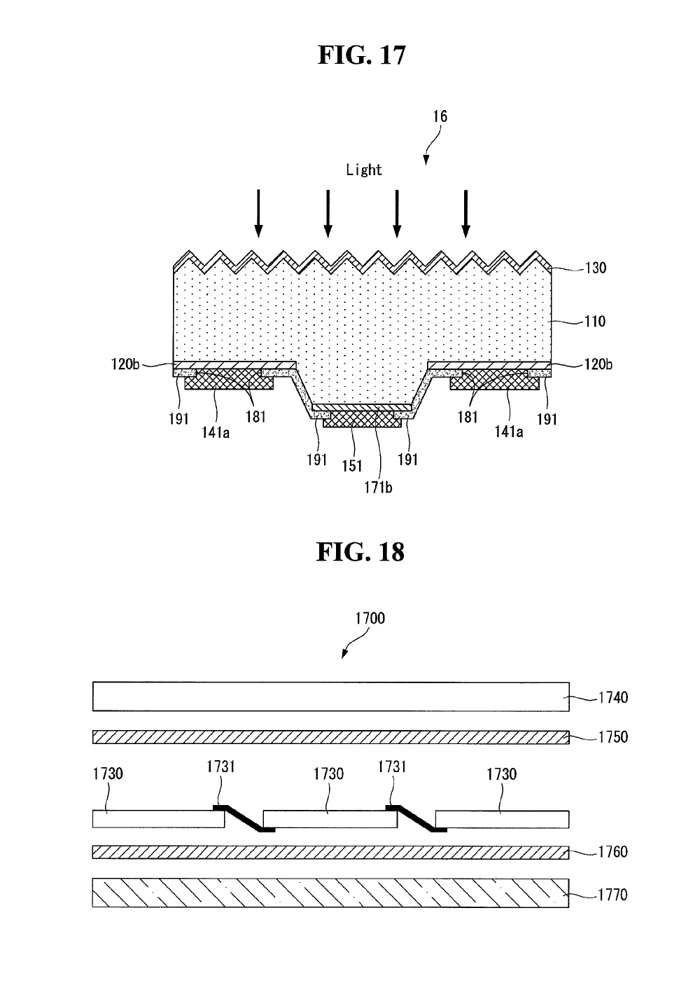

Next, with reference to FIG. 18, a solar cell module 1700 according to an embodiment of the present invention is described.

FIG. 18 illustrates a schematic cross-sectional view of a solar cell module according to an embodiment of the present invention.

With reference to FIG. 18, a solar cell module 1700 according to the present embodiment includes a plurality of solar cells 1730, protecting films 1750 and 1760 protecting the plurality of solar cells 1730, a transparent sealing member 1740 disposed on the protecting film (hereinafter, it is referred to as ‘an upper protecting film’) 1750 located to the direction of a light receiving surface of the solar cell 1730, and a back sheet 1770 disposed below the protecting film (hereinafter, it is referred to as ‘a lower protecting film’) 1760 located in the opposite of the light receiving surface where no light is incident.

The back sheet 1770 prevents moisture from penetrating through the rear surface of the solar cell module 10, protecting the solar cells 1730 from the outside environment. The back sheet 1770 may have a multi-layered structure such as a layer preventing penetration of moisture and oxygen, a layer preventing chemical corrosion, and an insulating layer.

The upper and lower protecting films 1750 and 1760 prevents corrosion of metal due to penetration of moisture and protects the solar cell module 1700 from an impact. The upper and lower protecting films 1750 and 1760 closely integrated with the solar cells 1730 at the time of lamination process while the films 1750 and 1760 are disposed respectively at the upper and lower parts of the solar cells 1730. The protecting films 1750 and 1760 may be made from ethylene vinyl acetate (EVA), polyvinyl butyral, ethylene vinyl acetate partial oxide, silicon resin, ester resin, and olefin resin, etc.

The transparent sealing member 1740 disposed on the upper protecting film 1750 has a high transmittance and is made from tempered glass to prevent or reduce damage. At this time, the tempered glass may be low iron tempered glass which has low content (amount or density or amount) of iron. An embossing process may be applied to the inner surface of the transparent sealing member 1740 to improve a diffusion effect of light.

The plurality of solar cells 1730 are arranged in a matrix structure. Each solar cell 1730 is connected to other either by serial connection or parallel connection through a plurality of connecting units 1731.

For example, a plurality of first electrode charge collectors or a second electrode (or a plurality of second electrode charge collectors) of each solar cell 1730 is connected to a second electrode (or a plurality of second electrode charge collectors) or a plurality of first electrode charge collectors of a neighboring solar cell 1730 through the connecting units 1731.

Therefore, when the plurality of first electrode charge collectors and the second electrode are disposed on different planes from each other, as shown in FIG. 18, the connecting units 1731 are attached on the front surface and the rear surface of the substrate of the solar cells 1730. When the plurality of first electrode charge collectors are disposed on the rear surface of the substrate, the connecting units 1731 may only be attached on the rear surface of the substrate. In this case, since it is prevented or reduced, that parts of a light receiving surface of each solar cell 1730 are obstructed by connecting units 1731, an efficiency of the solar cell 1730 is increased.

In embodiments of the invention, reference to metallurgical grade includes upgraded metallurgical grade.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

1. A solar cell, comprising:
a substrate of a first conductive type;
at least one emitter region of a second conductive type opposite to the first conductive type, and disposed at the substrate;
a plurality of first electrodes electrically connected to the at least one emitter region; and
at least one second electrode electrically connected to the substrate,
wherein the substrate is a silicon substrate of a metallurgical grade.

2-3. (canceled)

4. The solar cell of claim 1, wherein the substrate comprises at least one of aluminum (Al) and iron (Fe).

5. (canceled)

6. The solar cell of claim 4, wherein a density of Al is about 0.01 ppmw to about 0.8 ppmw, and a density of Fe is about 0.001 ppmw to about 1.0 ppmw.

7. The solar cell of claim 1, wherein the at least one emitter region comprises a high density doped part, and a total doped density of activated impurities in the high density doped part is about 4×10²⁰ atoms/cm³-to about 6×10²⁰ atoms/cm³.

8. The solar cell of claim 7, wherein the high density doped part has a depth of about 0.03 μm or less.

9. The solar cell of claim 7, wherein the at least one emitter region has a total thickness of about 0.25 μm.

10. The solar cell of claim 7, wherein a total doped density of activated impurities in the at least one emitter region is about 1×10¹⁹ atoms/cm³ to about 5×10¹⁹ atoms/cm³.

11. The solar cell of claim 1, wherein the substrate comprises a textured surface having a plurality of projections.

12. The solar cell of claim 1, wherein each of the plurality of projections has a width and a height of about 100 nm to about 500 nm.

13. The solar cell of claim 1, further comprising a passivation layer positioned on a surface of the substrate, on which light is not incident.

14. The solar cell of claim 13, wherein the passivation layer comprises a plurality of openings, and the at least one second electrode is electrically connected to the substrate through the plurality of openings.

15-22. (canceled)

23. The solar cell of claim 1, further comprising a plurality of first electrode charge collectors disposed opposite to the plurality of first electrodes with respect to the substrate, wherein the substrate comprises a plurality of through holes, and the plurality of first electrode charge collectors are connected to the plurality of first electrodes through the plurality of through holes.

24. The solar cell of claim 1, wherein the at least one emitter region comprises a first part, and a second part having an impurity density lower than an impurity density of the first part, and the plurality of first electrodes are connected to the first part.

25. The solar cell of claim 1, wherein the at least one emitter region is positioned on a surface of the substrate, on which light is not incident.

26. The solar cell of claim 1, further comprising at least one back surface field region positioned between the substrate and the at least one second electrode and electrically separated from the at least one emitter region.

27. The solar cell of claim 1, wherein the substrate has bulk a lifetime of about 0.1 μs to about 2 μs.

28. The solar cell of claim 27, wherein the substrate includes boron and density of the boron is about 3×10¹⁶ to about 5×10¹⁸atoms/cm³.

29. The solar cell of claim 27, wherein the substrate includes oxygen and density of the oxygen is about 1×10¹⁸ to about 1×10¹⁹ atoms/cm³.

30. The solar cell of claim 27, wherein the substrate includes carbon and density of the carbon is about 1×10¹⁶ to about 1×10¹⁹ atoms/cm³.

31. A solar cell, comprising:
a substrate of a first conductive type;
at least one emitter region of a second conductive type opposite to the first conductive type, and disposed at the substrate;
a plurality of first electrodes electrically connected to the at least one emitter region; and
at least one second electrode electrically connected to the substrate,
wherein the substrate has a purity level of 5N or less.

32-47. (canceled)
